(19) United States
(12) Patent Application Publication
(10) Pub. No.: US 2016/0099285 A1
(43) Pub. Date: Apr. 7, 2016

(54) METHOD FOR MANUFACTURING SOLID-STATE IMAGING DEVICE AND METHOD FOR MANUFACTURING CAMERA MODULE

(71) Applicant: Kabushiki Kaisha Toshiba, Minato-ku (JP)

(72) Inventors: Yoshiharu KUMAGAI, Morioka (JP); Junichi ABE, Kitakami (JP); Hironori TAKAHASHI, Kitakami (JP); Sonomi TAKAHASHI, Kitakami (JP); Hiroshi YOSHIKAWA, Kawasaki (JP); Shinobu TAKAHASHI, Kitakami (JP)

(73) Assignee: Kabushiki Kaisha Toshiba, Minato-ku (JP)

(21) Appl. No.: 14/843,485

(22) Filed: Sep. 2, 2015

(30) Foreign Application Priority Data
Oct. 3, 2014 (JP) 2014-204710

(51) Int. Cl. H01L 27/146

(52) U.S. Cl. CPC H01L 27/14687; H01L 27/14685

(57) ABSTRACT

Certain embodiments provide a method for manufacturing a solid-state imaging device including: forming a sensor chip fixed to a supporting substrate by a first adhesive; peeling off the sensor chip from the supporting substrate by softening the first adhesive; and fixing the peeled off sensor chip onto a curved surface of a mounting body to allow the sensor chip to be curved along the curved surface.

### CROSS REFERENCE TO RELATED APPLICATIONS

This application is based upon and claims the benefit of priority from the prior Japanese Patent Application No. 2014-204710 filed in Japan on Oct. 3, 2014; the entire contents of which are incorporated herein by reference.

### FIELD

Embodiments described herein relate generally to method for manufacturing a solid-state imaging device and method for manufacturing a camera module.

### BACKGROUND

In general, a lens has aberration. Accordingly, a lens unit is configured by causing a plurality of lenses to overlap each other in an optical axis direction in order to suppress a blur and distortion in image formation caused by the aberration. When such type of lens unit is applied to, for example, a camera module, the camera module is increased in size in a height direction.

Meanwhile, there is a demand for thinning regarding a mobile phone or the like to which such a camera module is mounted, for example. Accordingly, the camera module also needs to be thinned.

A means for causing a solid-state imaging device, which serves as a sensor chip to be mounted to a camera module, to be curved depending on aberration of a lens unit to be used in the module has been known as a means for realizing the thinning of the camera module while suppressing the blur and distortion in the image formation caused by the lens aberration. According to this means, it is possible to reduce the number of lenses to be included in the lens unit, and thus, the thinning of the camera module becomes possible.

Such a camera module is manufactured, for example, in the following manner. First, the solid-state imaging device is thinned until having a thickness of equal to or less than 100 μm, for example, in order to enable the solid-state imaging device to be curved. Subsequently, the thinned solid-state imaging device is bent using a desired means, and then is mounted onto a mounting substrate such as a printed wiring board. Thereafter, a lens holder, which includes at least the lens unit inside thereof, is mounted onto the mounting substrate so as to cover the solid-state imaging device. In this manner, the camera module is manufactured. However, since the solid-state imaging device is extremely thin as described above, the following problems are generated.

The thin solid-state imaging device is manufactured in the following manner, in general. First, a plurality of the thin solid-state imaging devices is collectively formed on a wafer. Next, the wafer is attached to a dicing tape, and then the plurality of solid-state imaging devices formed on the wafer is divided into individuals in the state of being supported by the dicing tape. Finally, the thin solid-state imaging device divided into the individual is pushed up by a pin so as to be peeled off from the dicing tape. In this manner, the thin solid-state imaging device is formed.

However, there occurs a problem that the solid-state imaging device is damaged when the thin solid-state imaging device is pushed up by the pin and peeled off from the dicing tape. Thus, a manufacturing yield of the solid-state imaging device decreases. Incidentally, when the solid-state imaging device is pushed up by the pin and peeled off from the dicing tape, a large force is topically applied with respect to the solid-state imaging device. Accordingly, even in a case where the solid-state imaging device is thickened in order to suppress the damage on the solid-state imaging device, there still are some cases where the solid-state imaging device is damaged.

### BRIEF DESCRIPTION OF THE DRAWINGS

FIG. 1 is a cross-sectional view of a main section of a camera module having a solid-state imaging device to be manufactured by a method for manufacturing a solid-state imaging device according to a first embodiment,

FIG. 2 is a cross-sectional view of a main section illustrating the solid-state imaging device to be manufactured by the method for manufacturing the solid-state imaging device according to the first embodiment, the solid-state imaging device to be applied to the camera module illustrated in FIG. 1,

FIG. 3A is a diagram illustrating a manufacturing process of the solid-state imaging device according to the first embodiment, and a top view illustrating a first wafer,

FIG. 3B is a diagram illustrating the solid-state imaging device manufacturing process according to the first embodiment, and a cross-sectional view of the first wafer taken along a dashed line X-X′ of FIG. 3A,

FIG. 4 is a cross-sectional view illustrating the solid-state imaging device manufacturing process according to the first embodiment, and corresponding to FIG. 2,

FIG. 5 is a cross-sectional view illustrating the solid-state imaging device manufacturing process according to the first embodiment, and corresponding to FIG. 2,

FIG. 6 is a cross-sectional view illustrating the solid-state imaging device manufacturing process according to the first embodiment, and corresponding to FIG. 2,

FIG. 7A is a diagram illustrating the solid-state imaging device manufacturing process according to the first embodiment, and a top view illustrating a second wafer,

FIG. 7B is a diagram illustrating the solid-state imaging device manufacturing process according to the first embodiment, and a cross-sectional view of the second wafer taken along a dashed line Y-Y′ of FIG. 7A,

FIG. 8 is a cross-sectional view illustrating the solid-state imaging device manufacturing process according to the first embodiment, and corresponding to FIG. 2,

FIG. 9 is a cross-sectional view illustrating the solid-state imaging device manufacturing process according to the first embodiment, and corresponding to FIG. 2,

FIG. 10 is a cross-sectional view illustrating the solid-state imaging device manufacturing process according to the first embodiment, and corresponding to FIG. 2,

FIG. 11 is a cross-sectional view illustrating the solid-state imaging device manufacturing process according to the first embodiment, and corresponding to FIG. 2,

FIG. 12 is a cross-sectional view illustrating a manufacturing process of the camera module having the solid-state imaging device to be manufactured by the method for manufacturing the solid-state imaging device according to the first embodiment, and corresponding to FIG. 1,

FIG. 13 is a cross-sectional view illustrating the manufacturing process of the camera module having the solid-state imaging device to be manufactured by the method for manufacturing the solid-state imaging device according to the first embodiment, and corresponding to FIG. 1,

FIG. 14 is a cross-sectional view of a main section of a camera module having a solid-state imaging device to be manufactured by the method for manufacturing the solid-state imaging device according to a second embodiment,

FIG. 15 is a cross-sectional view of a main section illustrating the solid-state imaging device to be manufactured by the method for manufacturing the solid-state imaging device according to the second embodiment, the solid-state imaging device to be applied to the camera module illustrated in FIG. 14,

FIG. 16 is a cross-sectional view illustrating the solid-state imaging device manufacturing process according to the second embodiment, and corresponding to FIG. 15,

FIG. 17 is a cross-sectional view illustrating the solid-state imaging device manufacturing process according to the second embodiment, and corresponding to FIG. 15,

FIG. 18 is a cross-sectional view illustrating the solid-state imaging device manufacturing process according to the second embodiment, and corresponding to FIG. 15, and

FIG. 19 is a cross-sectional view illustrating the solid-state imaging device manufacturing process according to the second embodiment, and corresponding to FIG. 15.

### DESCRIPTION OF THE EMBODIMENTS

Certain embodiments provide a method for manufacturing a solid-state imaging device including: forming a sensor chip fixed to a supporting substrate by a first adhesive; peeling off the sensor chip from the supporting substrate by softening the first adhesive; and fixing the peeled off sensor chip onto a curved surface of a mounting body to allow the sensor chip to be curved along the curved surface.

Certain embodiments provide a method for manufacturing a solid-state imaging device including: fixing a plurality of sensor chips formed on a top surface of a first wafer to a supporting substrate by a first adhesive; dividing the plurality of sensor chips into individuals in the state of being fixed to the supporting substrate; forming a plurality of mounting bodies each having a curved surface curved at a desired curvature on a second wafer; peeling off the plurality of sensor chips divided into individuals from the supporting substrate by softening the first adhesive; fixing each of the plurality of peeled off sensor chips onto the curved surface of the mounting body to allow the sensor chip to be curved along the curved surface; and cutting the second wafer.

Certain embodiments provide a method for manufacturing a camera module including: forming a solid-state imaging device by forming a sensor chip fixed to a supporting substrate by a first adhesive, peeling off the sensor chip from the supporting substrate by softening the first adhesive, and fixing the peeled off sensor chip onto a curved surface of a mounting body to allow the sensor chip to be curved along the curved surface; mounting the solid-state imaging device onto a top surface of a mounting substrate; and fixing a lens holder, which has a lens unit configured using one or more of lenses, is fixed to the top surface of the mounting substrate to surround the solid-state imaging device.

Hereinafter, a description will be made regarding methods for manufacturing a solid-state imaging device and methods for manufacturing a camera module according to embodiments with reference to the drawings.

### First Embodiment

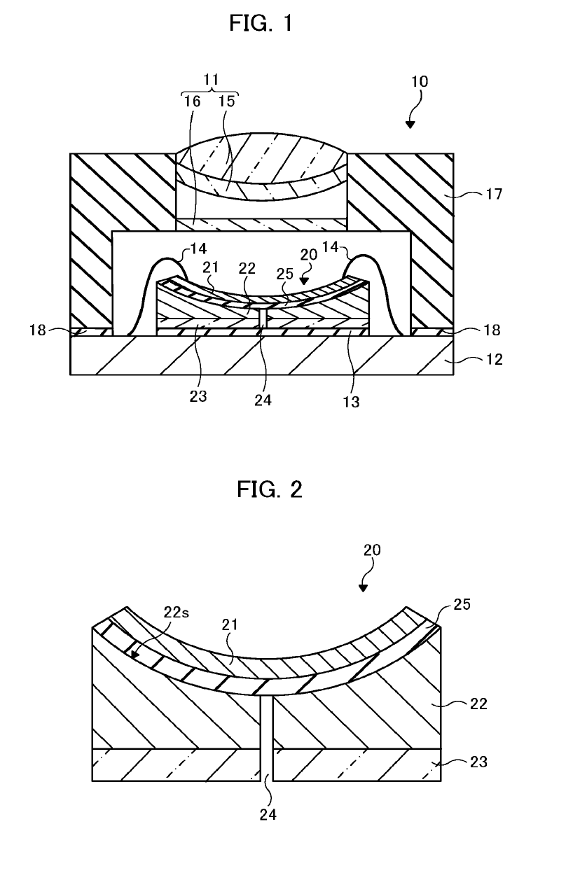

FIG. 1 is a cross-sectional view of a main section of a camera module having a solid-state imaging device to be manufactured by a method for manufacturing the solid-state imaging device according to a first embodiment. A camera module 10 has a solid-state imaging device 20 and an optical system 11 that condenses a desired light to the solid-state imaging device 20.

The solid-state imaging device 20 is fixed via an adhesive 13 to a top surface of a mounting substrate 12, which is a printed wiring board, for example. Further, a thin sensor chip 21, which will be described later, of the solid-state imaging device and the mounting substrate 12 are electrically connected to each other by a conductor 14, for example, a wire or the like.

The optical system 11 includes a lens unit 15 and an infrared cutoff filter 16. The lens unit 15 is fixed to inside of a lens holder 17, and is configured using one or more of lenses. The infrared cutoff filter 16 is disposed below the lens unit 15, for example, inside the lens holder 17.

The lens holder 17 having the optical system 11 is configured using a cylindrical resin body having a light shielding property. The lens holder 17 is disposed on the top surface of the mounting substrate 12 so as to surround the solid-state imaging device 20, and is fixed by an adhesive 18.

FIG. 2 is a cross-sectional view of a main section of the solid-state imaging device 20 to be manufactured by the method for manufacturing the solid-state imaging device according to the first embodiment. As illustrated in FIG. 2, the solid-state imaging device 20 is configured of a mounting body 22 and the thin sensor chip 21.

The mounting body 22 is a block body of a rectangular parallelepiped shape having substantially a square bottom surface, and a top surface opposite to the bottom surface of the block body is curved in a desired shape. Hereinafter, the top surface which is curved as above will be referred to as a curved surface 22s.

The mounting body 22 causes the thin sensor chip 21 to be curved in a desired shape by disposing the thin sensor chip 21 on the curved surface 22s, along this surface 22s. The mounting body 22 is configured using metal manufactured using an electroforming technique in order to form the curved surface 22s having a desired curvature, for example, with high accuracy. Incidentally, the mounting body 22 may be manufactured using any material other than metal as long as capable of forming the curved surface 22s having the desired curvature, and may be manufactured using metal formed by a means other than the electroforming technique.

Incidentally, a supporting substrate 23, which is a glass substrate or the like, for example, is provided on the bottom surface of the mounting body 22, but the supporting substrate 23 is formed for convenience of the manufacturing process, and is not necessarily provided.

A through hole 24 that penetrates through the supporting substrate 23 and the mounting body 22, and reaches the curved surface 22s of the mounting body is provided in the mounting body 22 having the supporting substrate 23. The through hole 24 is a hole for sucking the thin sensor chip 21. The thin sensor chip 21 is disposed on the curved surface 22s along this surface 22s by being sucked onto the curved surface 22s of the mounting body 22 through the through hole 24.

Incidentally, there is provided one through hole 24 in each of FIG. 1 and FIG. 2, but may be provided in a plurality of points.

The thin sensor chip 21 to be disposed on the curved surface 22s of the mounting body 22 has a light receiving region, which is formed by arranging a plurality of pixels on the semiconductor substrate, on the top surface thereof. The thin sensor chip 21 photoelectrically converts light received in the light receiving region into an electrical signal and outputs the signal. The thin sensor chip 21 is a CMOS sensor formed on a silicon substrate as an example of the semiconductor substrate. The thin sensor chip is formed in a quadrangular flat plate having a thickness of about 100 μm, and is curved along a curved surface 22s of the mounting body 22, and further, is curved at a degree that allows the aberration due to the lens unit 15 (FIG. 1) to be corrected. The thin sensor chip 21 is fixed onto the curved surface 22s of the mounting body 22 by an adhesive 25, for example, having a light curability or a thermosetting property.

The thin sensor chip 21, which is curved in such a manner, is disposed inside the camera module 10 as illustrated in FIG. 1. Accordingly, it is possible to cause the light taken inside the lens holder 17 by the lens unit 15 to be substantially vertically incident on the light receiving region of the thin sensor chip 21. Thus, a lens for correcting the aberration that the lens unit 15 has is not required, and it is possible to reduce the number of lenses to be included in the lens unit 15 of the camera module as compared to the camera module having a flat solid-state imaging device.

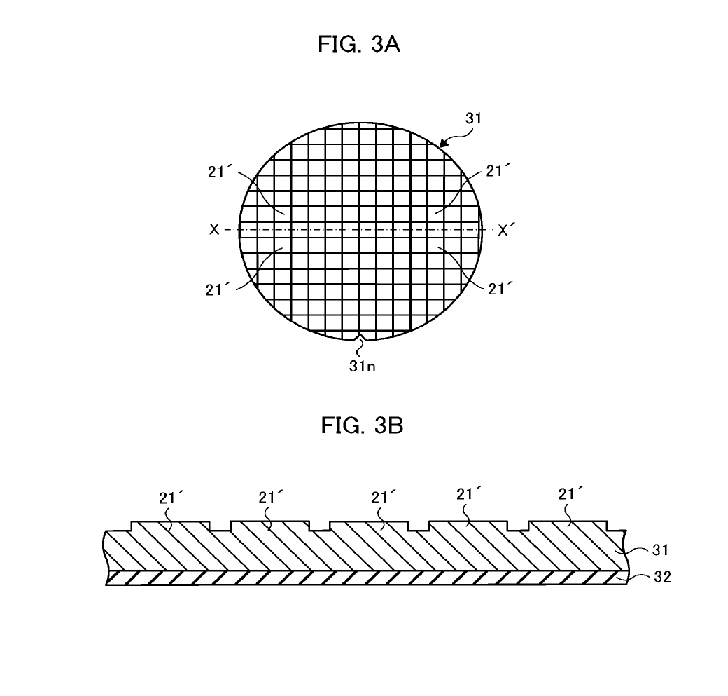

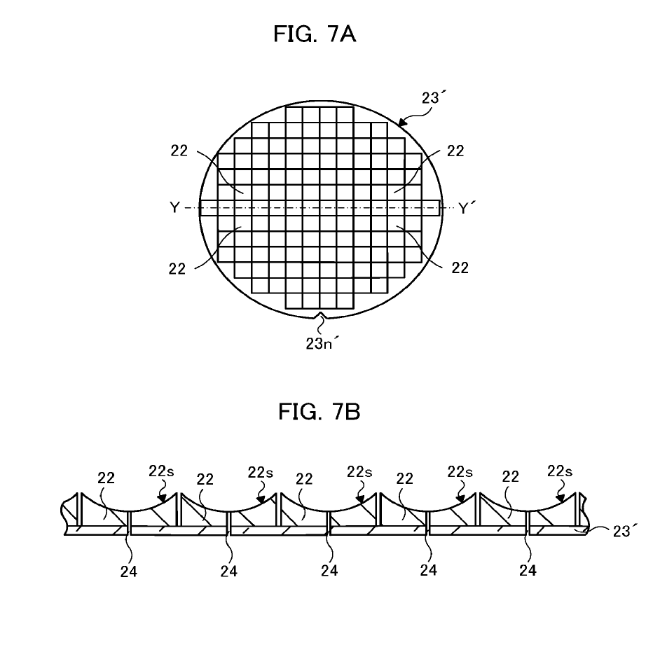

Next, a description will be made regarding the method for manufacturing the solid-state imaging device according to the first embodiment with reference to FIG. 3A to FIG. 11. Incidentally, except for FIG. 3A and FIG. 7A, each drawing is a cross-sectional view illustrating the solid-state imaging device manufacturing process according to the first embodiment, and corresponding to FIG. 2. FIG. 3A is a top view illustrating a first wafer in a process illustrated in FIG. 3B, and FIG. 7A is a top view illustrating a second wafer in a process illustrated in FIG. 7B.

First, as illustrated in FIG. 3A and FIG. 3B, a plurality of sensor chips 21′ is formed in a lattice shape, for example, on a top surface of a silicon wafer 31, for example, as the first wafer. Each of the sensor chips 21′ is a CMOS sensor, for example.

Subsequently, a dicing tape 32 is attached to a rear surface of the silicon wafer 31, and the silicon wafer 31 between the plurality of sensor chips 21′ is subjected to half-dicing so as to have a desired depth from the top surface. The half-dicing is performed, for example, by about equal to or less than 1/10 of the thickness of the silicon wafer 31.

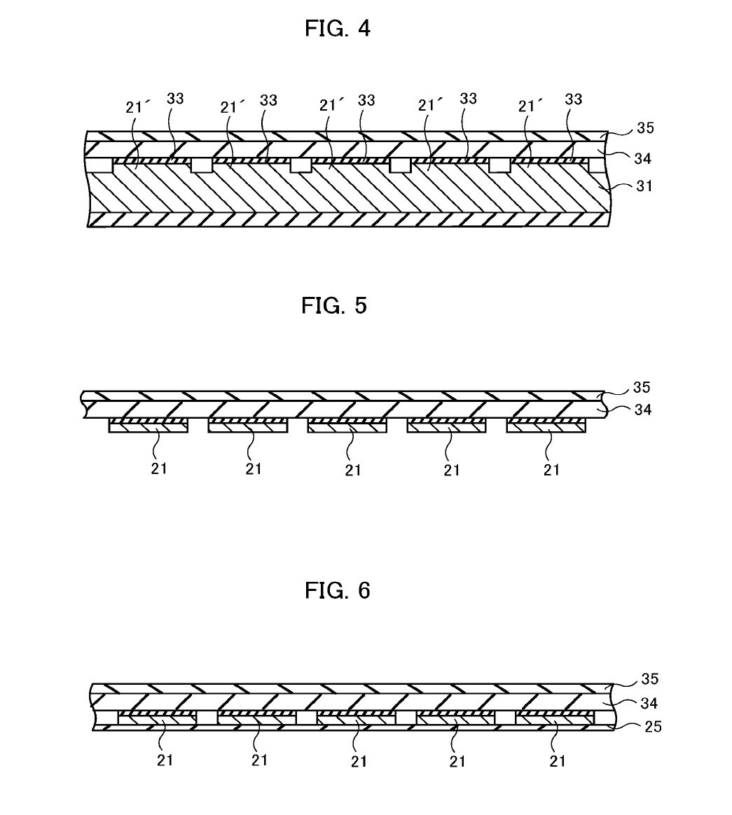

Next, as illustrated in FIG. 4, the top surface (top surface including the light receiving region of the plurality of sensor chips 21′) of the silicon wafer 31 on which the half-dicing is performed is attached to a first surface of the supporting substrate 34, for example, the glass substrate or the like using an adhesive 33, thereby fixing the silicon wafer 31 to the supporting substrate 34. Further, a BSG tape 35 serving as a top surface protective tape is affixed to a second surface, which faces the first surface, of the supporting substrate 34.

An adhesive of which an adhesive force decreases by being softened depending on a desired condition is used as the adhesive 33 to be used in this process. For example, an optical plastic adhesive that is softened by irradiation of UV light, or a thermoplastic adhesive that is softened by being heated to equal to or higher than a predetermined temperature is applied as the adhesive 33. Incidentally, in the present application, the “softening” of the adhesive means that the adhesive becomes soft, or the adhesive is melt.

Next, as illustrated in FIG. 5, the silicon wafer 31 fixed to the supporting substrate 34 is polished from the rear surface. The polishing is performed until the plurality of sensor chips 21′ formed on the top surface of the silicon wafer 31 is divided into individuals, and further, the plurality of sensor chips 21′ is thinned so as to have a desired thickness (for example, equal to or less than 100 μm). In this manner, a plurality of the thin sensor chips 21 having the desired thickness is formed in the state of being fixed to the supporting substrate 34.

Next, as illustrated in FIG. 6, a DAF (Die Attach Film) is attached, as an adhesive 25, to each rear surface of the plurality of thin sensor chips 21. For example, a light curable adhesive is used as the DAF, but a thermosetting adhesive may be used, and another adhesive may also be used.

On the other hand, as illustrated in FIG. 7A and FIG. 7B, a plurality of the mounting bodies 22 is arranged and fixed to a top surface of a supporting wafer 23′ serving as the second wafer. The supporting wafer 23′ is, for example, a glass wafer. In addition, the mounting body 22 is a metal block having a rectangular parallelepiped shape provided with the substantially square bottom surface and the curved surface 22s curved at a desired curvature on a surface on an opposite side of the bottom surface, and is manufactured using, for example, the electroforming technique. The plurality of mounting bodies 22, configured in such a manner, is disposed in a lattice shape so as to be spaced apart from each other at a desired interval on the top surface of the supporting wafer 23′, and fixed.

Incidentally, the plurality of mounting bodies 22 may be arranged in a lattice shape so as to be in contact with each other on the top surface of the supporting wafer 23′, and fixed.

After the plurality of mounting bodies 22 is formed on the top surface of the supporting wafer 23′ in such a manner, for example, the through hole 24, which penetrates through the supporting wafer 23′ and the mounting body 22, and reaches the curved surface 22s is formed for each of the mounting bodies 22 by, for example, etching. Although not illustrated, a plurality of the through holes 24 may be formed for each of the mounting bodies 22. In addition, the through hole 24 may be formed such that a through hole is provided in each of a predetermined position of the supporting wafer 23′ and a predetermined position of the mounting body 22, and then, both the through holes are caused to communicate with each other when the plurality of mounting bodies 22 is disposed and fixed on the top surface of the supporting wafer 23′.

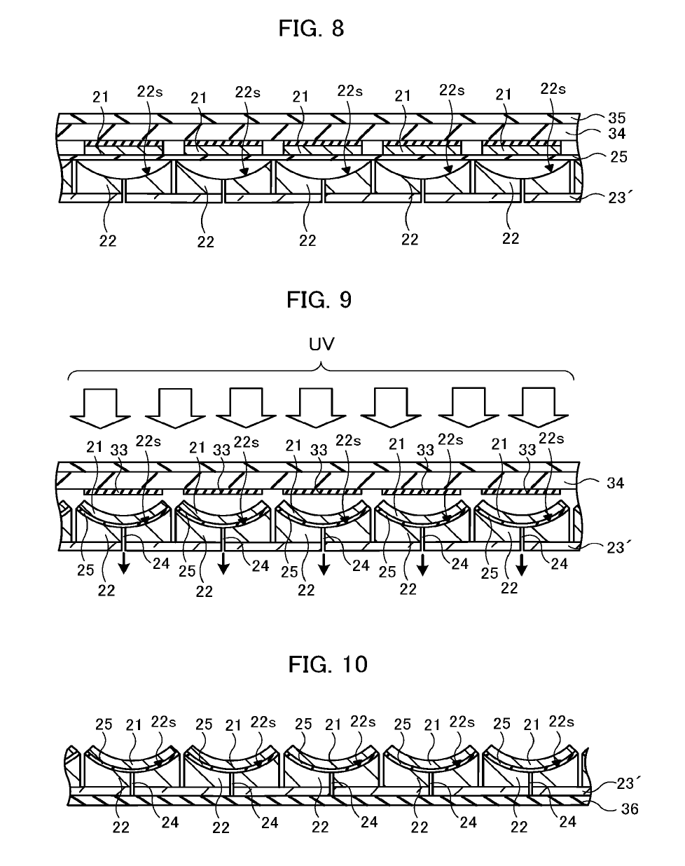

Next, as illustrated in FIG. 8, the plurality of thin sensor chips 21 fixed to the supporting substrate 34 is aligned and disposed on the supporting wafer 23′ by performing image processing using a notch 31n (FIG. 3A) of the silicon wafer 31 and a notch 23n′ (FIG. 7A) of the supporting wafer 23′. In this manner, each of the thin sensor chips 21 is disposed above the curved surface 22s of each of the mounting bodies 22.

Thereafter, as illustrated in FIG. 9, the adhesive 33 that fixes the plurality of thin sensor chips 21 to the supporting substrate 34 is softened. In addition, at the same time as the softening of the adhesive 33, the thin sensor chip 21 is sucked, by a desired suction force, from the rear surface of the supporting wafer 23′ using the through hole 24 that penetrates through the supporting wafer 23′ and the mounting body 22. For example, the softening of the adhesive 33 is performed by irradiating the adhesive 33 with the UV light in a case where the adhesive 33 is the optical plastic adhesive. Each of the thin sensor chips 21 is peeled off from the supporting substrate 34 by the softening of the adhesive 33. Further, each of the thin sensor chips 21 peeled off from the supporting substrate 34 by the suction through the through hole 24 is curved along the curved surface 22s of the mounting body 22. The curved thin sensor chip 21 is fixed onto the curved surface 22s by the adhesive 25 such as the DAF.

Incidentally, in a case where the adhesive 33 is the thermoplastic adhesive, the adhesive 33 is softened by being heated to a predetermined temperature so that each of the thin sensor chips 21 may be peeled off from the supporting substrate 34.

In this process, the thin sensor chip 21 is peeled off from the supporting substrate 34 by softening the adhesive 33. In this manner, the thin sensor chip 21 is peeled off from the supporting substrate 34 without applying a stress on the chip 21, and thus, it is possible to peel off the thin sensor chip 21 from the supporting substrate 34 without damage. As a result, it is possible to dispose the undamaged and normal thin sensor chip 21 on the curved surface 22s of the mounting body 22.

Next, for example, the supporting wafer 23′ is irradiated with the UV light from the rear surface side. In this manner, the irradiated UV light reaches the adhesive 25 through the through hole 24. As a result, the adhesive 25 is cured, and the thin sensor chip 21 is fixed onto the curved surface 22s of the mounting body 22. Further, as illustrated in FIG. 10, a dicing tape 36 is attached onto the rear surface of the supporting wafer 23′.

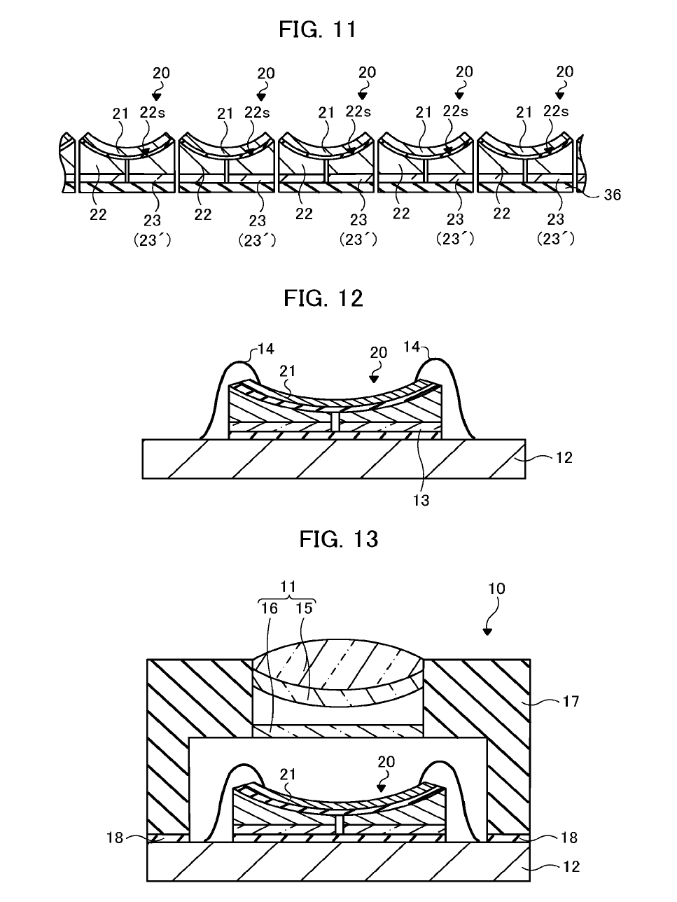

Thereafter, as illustrated in FIG. 11, the supporting wafer 23′ exposed from a portion between the mounting bodies 22 is cut together with the dicing tape 36. In this manner, the solid-state imaging device 20 is manufactured. The manufactured solid-state imaging device 20 is provided with the mounting body 22 having the curved surface 22s, and the thin sensor chip 21 fixed along the curved surface 22s. Further, the supporting substrate 23 to be formed by the division of the supporting wafer 23′ is disposed on the bottom surface of the mounting body 22.

Incidentally, in the dicing process illustrated in FIG. 11 in a case where the plurality of mounting bodies 22 is disposed so as to be in contact with each other on the top surface of the supporting wafer 23′, the mounting body 22 is also cut together with the supporting wafer 23′ and the dicing tape 36. However, in a case where the mounting body 22 is configured using metal, for example, the metal, which is a different type of material from the supporting wafer 23′, for example, glass or the like, needs to be cut together with the cutting of the supporting wafer 23′. Thus, the dicing becomes difficult. Accordingly, it is preferable that the mounting bodies 22 be disposed on the top surface of the supporting wafer 23′ so as to be spaced apart from each other.

In addition, the DAF is cured by irradiating the supporting wafer 23′ with the UV light from the rear surface side, and causing the irradiated UV light to reach the adhesive 25 such as the DAF through the through hole 24. Thus, it is preferable that the supporting wafer 23′ that allows the UV light to be transmitted therethrough be applied as the second wafer on which the mounting body 22 is disposed, but the second wafer may not be the glass wafer in a case where the DAF is an adhesive other than the light curable adhesive.

Next, a description will be made regarding a method for manufacturing the camera module having the solid-state imaging device 20 manufactured by the method for manufacturing the solid-state imaging device according to the first embodiment with reference to FIG. 12 and FIG. 13. FIG. 12 and FIG. 13 are cross-sectional views illustrating the manufacturing method of the camera module having the solid-state imaging device configured as above, and corresponding to FIG. 1.

After the solid-state imaging device 20 is manufactured through the processes illustrated in FIG. 3A to FIG. 11, the adhesive 13 is applied to a predetermined position on the top surface of the mounting substrate 12, for example, the printed wiring board or the like, and then the solid-state imaging device 20 is fixed onto the top surface of the mounting substrate 12 by the adhesive 13 as illustrated in FIG. 12. Further, the thin sensor chip 21 of the solid-state imaging device 20 and a wiring (not illustrated) on the top surface of the mounting substrate 12 are connected to each other by the conductor 14 such as a wire. In this manner, the solid-state imaging device 20 is mounted onto the top surface of the mounting substrate 12.

Thereafter, as illustrated in FIG. 13, the adhesive 18 is applied in a ring shape onto the top surface of the mounting substrate 12 so as to surround the solid-state imaging device 20, and the lens holder 17, which is provided with the optical system 11 such as the lens unit 15 and the infrared cutoff filter 16, is fixed onto the top surface of the mounting substrate 12 by the adhesive 18. In this manner, the camera module 10 having the solid-state imaging device 20, of which the thin sensor chip 21 is curved, therein is manufactured.

According to the method for manufacturing the solid-state imaging device according to the first embodiment described above, there is no process of pressing a thin solid-state imaging device by a pin to be peeled off from the dicing tape as in the method for manufacturing a thin solid-state imaging device of the related art. In the method for manufacturing the solid-state imaging device according to the present embodiment and the method for manufacturing the camera module according to the present embodiment, there is the process of peeling off the thin sensor chip 21 from the supporting substrate 34, but this process is performed by softening the adhesive 33 that fixes the both. Accordingly, since there is no process of applying the stress to the thin sensor chip 21, the damage of the thin sensor chip 21 caused by the stress is suppressed, and it is possible to improve a manufacturing yield of the thin sensor chip 21.

In addition, according to the method for manufacturing the camera module having the solid-state imaging device manufactured by the method for manufacturing the solid-state imaging device according to the first embodiment, the solid-state imaging device 20 is manufactured by fixing the thin sensor chip 21 to the mounting body 22, and then this solid-state imaging device 20 is mounted to the mounting substrate 12. Accordingly, it is possible to mount the thin sensor chip 21 to be included in the solid-state imaging device 20 to the mounting substrate 12 with high accuracy, and further, it is possible to manufacture the camera module 10 with excellent reliability. Hereinafter, a description will be made in more detail regarding such an effect.

In a conventional method for manufacturing the camera module in which a solid-state imaging device, formed only of a thin sensor chip without being fixed to a mounting body, is curved and mounted to a mounting substrate, it is difficult to mount the solid-state imaging device to the mounting substrate with the high accuracy, and it is also difficult to manufacture a camera module having the high reliability.

In other words, in the conventional camera module manufacturing method, the solid-state imaging device, formed only of the thin sensor chip, is adsorbed by a collet, and the solid-state imaging device is moved to a predetermined position of the mounting substrate by moving the collet. After performing such an alignment process of the solid-state imaging device, the solid-state imaging device is curved by a desired means, and is mounted onto the mounting substrate using an adhesive. However, since the solid-state imaging device is thin, the solid-state imaging device is curved and deformed according to a shape of the collet by an adsorption force of the collet, and is moved onto the predetermined position of the mounting substrate in such a state. Thus, a positional deviation occurs by a reactive movement of recovering a normal shape (for example, a plate shape) by the solid-state imaging device when the solid-state imaging device is separated from the collet for the mounting. Thus, it is difficult to mount the solid-state imaging device to the mounting substrate with the high accuracy. Further, since the solid-state imaging device is brought into contact with the adhesive and mounted to the mounting substrate in the state of being curved and deformed, reliability of the adhesion deteriorates, and it is also difficult to manufacture the camera module having the high reliability.

On the contrary, in the method for manufacturing the camera module having the solid-state imaging device 20 manufactured by the method for manufacturing the solid-state imaging device according to the first embodiment, the solid-state imaging device 20 is manufactured by fixing the thin sensor chip 21 to the mounting body 22, and then this solid-state imaging device 20 is mounted to the mounting substrate 12. Accordingly, it is possible to suppress the deformation of the solid-state imaging device 20 caused by the adsorption force of the collet. Thus, the problem as described above is solved, it is possible to mount the solid-state imaging device 20 to the mounting substrate 12 with the high accuracy, and it is possible to manufacture the camera module 10 with the excellent reliability.

### Second Embodiment

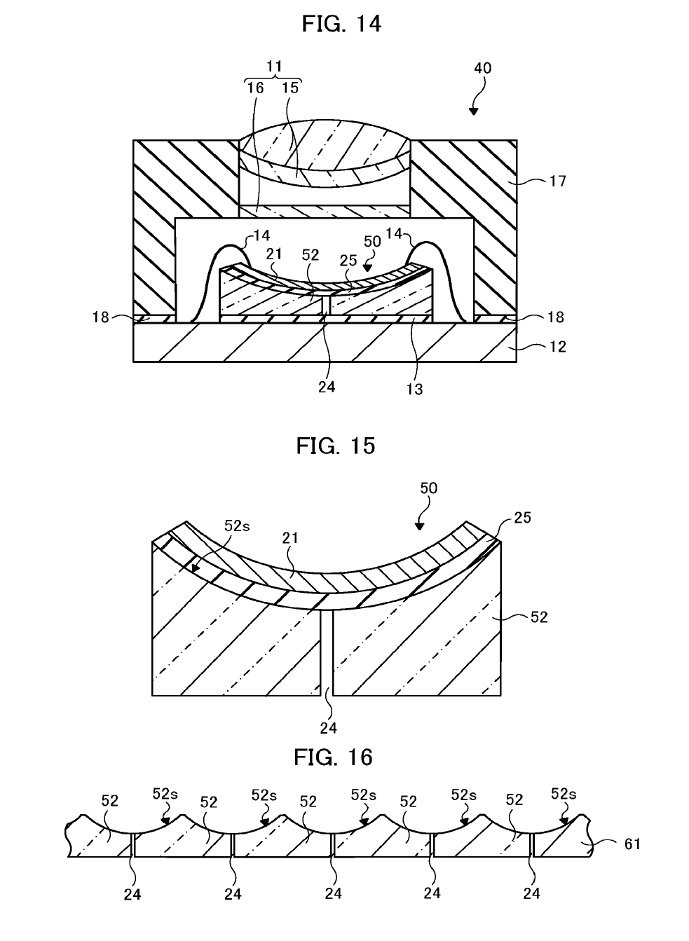

FIG. 14 is a cross-sectional view of a main section of a camera module having a solid-state imaging device manufactured by a method for manufacturing a solid-state imaging device according to a second embodiment. In addition, FIG. 15 is a cross-sectional view of a main section illustrating the solid-state imaging device to be manufactured by the method for manufacturing the solid-state imaging device according to the second embodiment. In a camera module 40 illustrated in FIG. 14 and a solid-state imaging device 50 illustrated in FIG. 15, a material configuring a mounting body 52 is different as compared to the camera module 10 illustrated in FIG. 1, and the solid-state imaging device 20 illustrated in FIG. 2. Incidentally, structures other than the mounting body 52 are the same as those of the camera module 10 illustrated in FIG. 1 and the solid-state imaging device 20 illustrated in FIG. 2, and thus, the same reference numerals are attached to the same points in each drawing, and descriptions for the same points will be omitted.

In the solid-state imaging device 50 illustrated in FIG. 14 and FIG. 15, a shape of the mounting body 52 is the same as that of the mounting body 22 to be applied to the solid-state imaging device 20 illustrated in FIG. 1 and FIG. 2. The mounting body of the solid-state imaging device 50 is formed using a dielectric material such as glass, which is a different point from the mounting body 22 to be applied to the solid-state imaging device 20 illustrated in FIG. 1 and FIG. 2.

Incidentally, although the supporting substrate 23, for example, the glass substrate or the like, is provided on the bottom surface of the mounting body 22 in the solid-state imaging device 20 illustrated in FIG. 1 and FIG. 2, the supporting substrate is not provided on a bottom surface of the mounting body 52 in the solid-state imaging device illustrated in FIG. 14 and FIG. 15.

Next, a description will be made regarding the method for manufacturing the solid-state imaging device according to the second embodiment with reference to FIG. 16 to FIG. 19. Each of FIG. 16 to FIG. 19 is a cross-sectional view illustrating the solid-state imaging device manufacturing process according to the second embodiment, and corresponding to FIG. 15.

Similarly to the method for manufacturing the solid-state imaging device according to the first embodiment, first, the plurality of thin sensor chips in the state of being fixed to the supporting substrate 34 is formed (FIG. 3A to FIG. 5), and the DAF is attached, as the adhesive 25, to the rear surface of the plurality of thin sensor chips 21 (FIG. 6) even in the method for manufacturing the solid-state imaging device according to the second embodiment.

On the other hand, as illustrated in FIG. 16, a plurality of the mounting bodies 52 is formed in a lattice shape on a glass wafer 61 by processing a top surface of the glass wafer 61, for example, as the second wafer. It is possible to form the plurality of mounting bodies 52 by forming a plurality of curved surfaces 52s on the top surface of the glass wafer 61 by a sand blast method, for example, and further forming the plurality of through holes 24 so as to penetrate through the glass wafer 61.

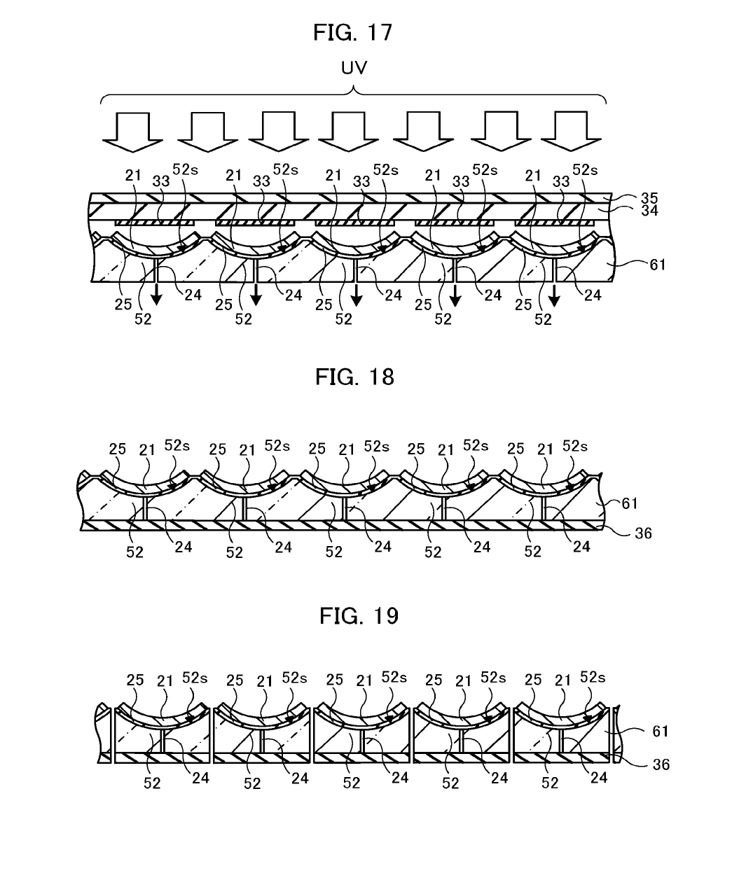

Next, each of the thin sensor chips 21 is disposed above the curved surface 52s of each of the mounting bodies 52 by aligning and disposing the supporting substrate 34 to which the plurality of thin sensor chips 21 is fixed on the glass wafer 61 on which the plurality of mounting bodies 52 is formed. Thereafter, as illustrated in FIG. 17, the adhesive 33 that fixes the plurality of thin sensor chips 21 to the supporting substrate 34 is softened, and further, the thin sensor chip 21 is sucked by a desired suction force using from a rear surface side of the glass wafer 61 using the through hole 24 that penetrates through the glass wafer 61 (the mounting body 52). For example, the softening of the adhesive 33 is performed by irradiating the adhesive 33 with the UV light in a case where the adhesive 33 is the optical plastic adhesive. Each of the thin sensor chips 21 is peeled off from the supporting substrate 34 by the softening of the adhesive 33. In addition, each of the thin sensor chips 21 peeled off by the suction using the through hole 24 is curved along the curved surface 52s of the mounting body 52, and is disposed on the curved surface 52s by the adhesive such as the DAF in such a state.

Incidentally, in a case where the adhesive 33 is the thermoplastic adhesive, the adhesive 33 is softened by being heated to a predetermined temperature so that each of the thin sensor chips 21 may be peeled off from the supporting substrate 34.

In this process, the thin sensor chip 21 is peeled off from the supporting substrate 34 by softening the adhesive 33. In this manner, the thin sensor chip 21 is peeled off from the supporting substrate 34 without applying the stress to the chip 21. Accordingly, it is possible to peel off the thin sensor chip 21 from the supporting substrate 34 without damage. As a result, it is possible to dispose the undamaged and normal thin sensor chip 21 on the curved surface 52s of the mounting body 52.

Next, the adhesive 25 is cured by irradiating the glass wafer 61 with the UV light from the rear surface side, for example, and the thin sensor chip 21 is fixed onto the curved surface 52s of the mounting body 52. Further, as illustrated in FIG. 18, the dicing tape 36 is attached onto the rear surface of the glass wafer 61.

Thereafter, as illustrated in FIG. 19, the glass wafer 61 exposed from a portion between the thin sensor chips 21 is cut together with the dicing tape 36. In this manner, the solid-state imaging device 50, which is provided with the mounting body 52 having the curved surface 52s on which the thin sensor chip is disposed, is manufactured.

Incidentally, the method for manufacturing the camera module having the solid-state imaging device 50 manufactured by the method for manufacturing the solid-state imaging device according to the second embodiment is a method for manufacturing the solid-state imaging device 50, manufactured as above, in the same manner as the method for manufacturing the camera module 10 described in the first embodiment. Accordingly, a description will be omitted regarding the method for manufacturing the camera module having the solid-state imaging device 50 manufactured by the method for manufacturing the solid-state imaging device according to the second embodiment.

Even in the method for manufacturing the solid-state imaging device according to the second embodiment described above, there is no process of pressing the thin solid-state imaging device by the pin to be peeled off from the dicing tape as in the method for manufacturing the thin solid-state imaging device of the related art. In the solid-state imaging device and the camera module manufacturing method according to the present embodiment, there is the process of peeling off the thin sensor chip 21 from the supporting substrate 34, but this process is performed by softening the adhesive 33 that fixes the both. Accordingly, since there is no process of applying the stress to the thin sensor chip 21, the damage of the thin sensor chip caused by the stress is suppressed, and it is possible to improve a manufacturing yield of the thin sensor chip 21.

In addition, even in the method for manufacturing the camera module having the solid-state imaging device manufactured by the method for manufacturing the solid-state imaging device according to the second embodiment, the solid-state imaging device 50 is manufactured by fixing the thin sensor chip 21 to the mounting body 52, and then, this solid-state imaging device 50 is mounted to the mounting substrate 12. Accordingly, it is possible to mount the thin sensor chip 21 to be included in the solid-state imaging device 50 to the mounting substrate 12 with the high accuracy, and further, it is possible to manufacture the camera module 40 with the excellent reliability because of the same reasons as in the method for manufacturing the camera module according to the first embodiment.

Further, in the method for manufacturing the solid-state imaging device according to the second embodiment, the plurality of mounting bodies 52 is formed in the glass wafer 61 by applying the glass wafer 61 as the second wafer and processing the glass wafer 61. Accordingly, it is possible to cause the UV light, used when the adhesive 25 between the mounting body 52 and the thin sensor chip 21 is cured, to reach the adhesive 25 from the entire surface of the rear surface side of the glass wafer 61. Accordingly, it is possible to cure the adhesive 25 in a shorter period of time as compared to the method for manufacturing the solid-state imaging device according to the first embodiment, and it is possible to fix the thin sensor chip 21 with respect to the mounting body 52 in a shorter period of time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the solid-state imaging device manufactured by the method for manufacturing the solid-state imaging device according to each embodiment described above has been applied to the camera module. However, the manufactured solid-state imaging device may be applied also to a digital camera or a single-lens reflex camera by providing a cover glass.

What is claimed is:

1. A method for manufacturing a solid-state imaging device comprising:
forming a sensor chip fixed to a supporting substrate by a first adhesive;
peeling off the sensor chip from the supporting substrate by softening the first adhesive; and
fixing the peeled off sensor chip onto a curved surface of a mounting body to allow the sensor chip to be curved along the curved surface.

2. The method for manufacturing the solid-state imaging device according to claim 1,
wherein the first adhesive is an adhesive that is softened by UV irradiation, and
the softening of the first adhesive is performed by irradiating the first adhesive with UV light.

3. The method for manufacturing the solid-state imaging device according to claim 1,
wherein the first adhesive is a thermoplastic adhesive, and
the softening of the first adhesive is performed by heating the first adhesive.

4. The method for manufacturing the solid-state imaging device according to claim 1,
wherein the sensor chip fixed to the supporting substrate is disposed on the mounting body, and then, the sensor chip is peeled off from the supporting substrate, and
the sensor chip peeled off from the supporting substrate is fixed onto the curved surface of the mounting body.

5. The method for manufacturing the solid-state imaging device according to claim 1,
wherein the mounting body has a through hole that penetrates through the mounting body,
the sensor chip peeled off from the supporting substrate is disposed on the curved surface by being sucked through the through hole, and
the sensor chip disposed on the curved surface is fixed onto the curved surface by curing a second adhesive that is interposed between the curved surface and the sensor chip.

6. The method for manufacturing the solid-state imaging device according to claim 5,
wherein the second adhesive is a light curable adhesive that is cured by irradiation of UV light, and
the second adhesive is cured by irradiating the UV light through the through hole.

7. The method for manufacturing the solid-state imaging device according to claim 5,
wherein the second adhesive is a light curable adhesive that is cured by irradiation of UV light,
the mounting body is a glass wafer through which the UV light is transmitted, and
the second adhesive is cured by irradiating the UV light transmitted through the mounting body.

8. A method for manufacturing the solid-state imaging device comprising:
fixing a plurality of sensor chips formed on a top surface of a first wafer to a supporting substrate by a first adhesive;
dividing the plurality of sensor chips into individuals in the state of being fixed to the supporting substrate;
forming a plurality of mounting bodies each having a curved surface curved at a desired curvature on a second wafer;
peeling off the plurality of sensor chips divided into individuals from the supporting substrate by softening the first adhesive;
fixing each of the plurality of peeled off sensor chips onto the curved surface of the mounting body to allow the sensor chip to be curved along the curved surface; and
cutting the second wafer.

9. The method for manufacturing the solid-state imaging device according to claim 8,
wherein the first adhesive is an adhesive that is softened by UV irradiation, and
the softening of the first adhesive is performed by irradiating the first adhesive with UV light.

10. The method for manufacturing the solid-state imaging device according to claim 8,
wherein the first adhesive is a thermoplastic adhesive, and
the softening of the first adhesive is performed by heating the first adhesive.

11. The method for manufacturing the solid-state imaging device according to claim 8,
wherein the plurality of sensor chips is divided into individuals by half-dicing of the first wafer between the plurality of sensor chips from a top surface, and thinning the first wafer by polishing a rear surface of the first wafer.

12. The method for manufacturing the solid-state imaging device according to claim 11,
wherein the rear surface of the first wafer is polished until each of the plurality of sensor chips is thinned.

13. The method for manufacturing the solid-state imaging device according to claim 8,
wherein the plurality of mounting bodies is formed using a electroforming technique, and
the plurality of mounting bodies is formed on the second wafer by fixing the plurality of mounting bodies formed using the electroforming technique to a top surface of the second wafer.

14. The method for manufacturing the solid-state imaging device according to claim 13,
wherein the plurality of mounting bodies is disposed on the top surface of the second wafer to be spaced apart from each other.

15. The method for manufacturing the solid-state imaging device according to claim 8,
wherein the plurality of mounting bodies is formed on the second wafer by processing a top surface of the second wafer.

16. The method for manufacturing the solid-state imaging device according to claim 8,
wherein the plurality of sensor chips fixed to the supporting substrate and divided into individuals is disposed on the plurality of mounting bodies, and then, the plurality of sensor chips is peeled off from the supporting substrate, and
each of the plurality of sensor chips peeled off from the supporting substrate is fixed onto the curved surface of the mounting body.

17. The method for manufacturing the solid-state imaging device according to claim 16,
wherein the mounting body has a through hole that penetrates through the mounting body and the first wafer,
each of the plurality of sensor chips peeled off from the supporting substrate is disposed on the curved surface by being sucked through the through hole, and
the sensor chip disposed on the curved surface is fixed onto the curved surface by curing a second adhesive that is interposed between the curved surface and the sensor chip.

18. The method for manufacturing the solid-state imaging device according to claim 17,
wherein the second adhesive is a light curable adhesive that is cured by irradiation of UV light, and
the second adhesive is cured by irradiating the UV light through the through hole.

19. The method for manufacturing the solid-state imaging device according to claim 17,
wherein the second adhesive is a light curable adhesive that is cured by irradiation of UV light,
the second wafer including the mounting body is a glass wafer through which the UV light is transmitted, and
the second adhesive is cured by irradiating the UV light transmitted through the second wafer including the mounting body.

20. A method for manufacturing a camera module comprising:
forming a solid-state imaging device by:
forming a sensor chip fixed to a supporting substrate by a first adhesive;
peeling off the sensor chip from the supporting substrate by softening the first adhesive; and
fixing the peeled off sensor chip onto a curved surface of a mounting body to allow the sensor chip to be curved along the curved surface;
mounting the solid-state imaging device onto a top surface of a mounting substrate; and
fixing a lens holder, which has a lens unit configured using one or more of lenses, is fixed to the top surface of the mounting substrate to surround the solid-state imaging device.
